(19) United States
(12) Patent Application Publication
(10) Pub. No.: US 2018/0218887 A1
(43) Pub. Date: Aug. 2, 2018

(54) PROCESSING APPARATUS FOR PROCESSING TARGET OBJECT

(71) Applicant: Tokyo Electron Limited, Tokyo (JP)

(72) Inventors: Takehiko Arita, Kurokawa-gun (JP); Akiyoshi Mitsumori, Kurokawa-gun (JP); Shin Yamaguchi, Kurokawa-gun (JP)

(21) Appl. No.: 15/885,951

(22) Filed: Feb. 1, 2018

(30) Foreign Application Priority Data
Feb. 2, 2017 (JP) 2017-017829

(51) Int. Cl. H01J 37/32; H01L 21/67; H01L 21/683

(52) U.S. Cl. CPC H01J 37/32724; H01L 21/67069; H01J 2237/334; H01L 21/67103; H01L 21/6831

(57) ABSTRACT

In a processing apparatus, a cooling table in which a coolant is flown includes first to third regions, and a path group of the coolant. The first region is provided at a center portion of the cooling table. The second region is provided to surround the first region. The third region is provided to surround the first and the second regions. The path group includes first to third paths. The first path to the third path are provided in the first region to the third region, respectively. A pipeline system of the coolant includes a first valve group and a second valve group. The first path and the second path, and the second path and the third path are connected via the first valve group. The chiller unit and the path group are connected via the second valve group.

### CROSS-REFERENCE TO RELATED APPLICATION

This application claims the benefit of Japanese Patent Application No. 2017-017829 filed on Feb. 2, 2017, the entire disclosures of which are incorporated herein by reference.

### TECHNICAL FIELD

The embodiments described herein pertain generally to a processing apparatus for processing a processing target object within a chamber.

### BACKGROUND

In a recent plasma etching process in which a relatively large heat input source is provided, in order to maintain a temperature of a wafer uniform, low and constant, there is proposed a direct expansion type temperature control system configured to be capable of performing a high-efficiency heat transfer. Especially, there is proposed a technique of gradually changing a shape of a coolant path provided in a mounting table (vaporizer) configured to mount the wafer thereon to render the heat transfer within the vaporizer uniform.

Patent Document 1 describes a technique regarding a plasma processing apparatus and a plasma processing method. The technique disclosed in Patent Document 1 is aimed at controlling a temperature of a semiconductor wafer at a high speed with uniformity within a surface thereof in a large heat input etching process. A ring-shaped coolant path is formed in a sample table. In consideration of the fact that a heat transfer rate of a coolant is largely changed from a coolant inlet port toward a coolant outlet port, there is adopted a structure in which a cross sectional area of the coolant path is increased from a first path toward a second path in order to maintain constant the heat transfer rate of the coolant within the coolant path.

Patent Document 2 discloses a technique regarding a plasma processing apparatus. The technique described in Patent Document 2 is directed to controlling a temperature of a wafer to be uniform within a surface thereof at a high speed within a wide temperature range when a large heat input etching process is performed by application of a high wafer bias power. A coolant path provided in an electrostatic attraction electrode is configured as a vaporizer, and a direct expansion type cooling cycle is formed by connecting this coolant path with a compressor, a condenser and a first expansion valve. Further, by providing a second expansion valve at the coolant path between the electrostatic attraction electrode and the compressor, a flow rate of the coolant is adjusted. The coolant path has a thin cylindrical structure.
Patent Document 1: Japanese Patent Laid-open Publication No. 2008-186856
Patent Document 2: Japanese Patent Laid-open Publication No. 2012-028811

### SUMMARY

In the aforementioned prior art, however, since the structure of the coolant path is predetermined, it may be difficult to achieve temperature adjustment in response to a change in a distribution of a heat input amount. In this regard, there is a demand for a technique capable of performing the temperature adjustment in response to the change in the distribution of the heat input amount.

In one exemplary embodiment, there is provided a processing apparatus for a processing target object. The processing apparatus for the processing target object includes a chamber main body; a mounting table which is provided within the chamber main body and configured to mount the processing target object thereon; a chiller unit configured to output a coolant; and a pipeline system which is connected to the chiller unit and configured to allow the coolant to flow therein. The mounting table includes a cooling table which is connected to the pipeline system and in which the coolant supplied through the pipeline system is flown; and an electrostatic chuck provided on the cooling table. The cooling table includes a first region, a second region, a third region, and a path group which is connected to the pipeline system and configured to allow the coolant to flow therethrough. The first region, the second region and the third region are arranged along a surface of the electrostatic chuck. The first region is provided at a center portion of the cooling table when viewed from above the electrostatic chuck. The second region is provided to surround the first region when viewed from above the electrostatic chuck. The third region is provided to surround the first region and the second region when viewed from above the electrostatic chuck. The path group includes a first path, a second path and a third path. The first path is provided in the first region. The second path is provided in the second region. The third path is provided in the third region. The pipeline system includes a first valve group and a second valve group. In the path group, the first path and the second path are connected with the first valve group therebetween, and the second path and the third path are connected with the first valve group therebetween. The chiller unit and the path group are connected with the second valve group therebetween.

In the processing apparatus, the first path, the second path and the third path of the path group for allowing the coolant to flow in the first region, the second region and the third region of the cooling table respectively are provided in the cooling table of the mounting table configured to mount the processing target object thereon; the first path and the second path are connected and the second path and the third path are connected with the first valve group therebetween; and the chiller unit and the path group provided in the cooling table are connected with the second valve group therebetween. Accordingly, by adjusting the opening/closing state of the first valve group and the opening/closing state of the second valve group, the path and the pressure of the coolant flowing in the cooling table can be adjusted for each of the first region, the second region and the third region of the cooling table individually, so that the temperature adjustment upon the cooling table can be performed in a detailed manner. Therefore, the temperature of the processing target object placed on the cooling table can be easily made approximately uniform regardless of the distribution of the heat input amount of the plasma.

The first valve group may include a first valve and a second valve. The first path and the second path may be connected with the first valve therebetween, and the second path and the third path may be connected with the second valve therebetween. Further, the connection between the first path and the second path and the connection between the second path and the third path are respectively accomplished with the separately provided valves therebetween. Thus, by adjusting these valves individually, the temperature adjustment upon each of the first region, the second region and the third region of the cooling table can be performed individually, so that more detailed temperature adjustment can be achieved.

An opening degree of the first valve and an opening degree of the second valve may be allowed to be varied. The first valve provided between the first path and the second path and the second valve provided between the second path and the third path are configured to vary the opening degrees thereof. Thus, by adjusting the opening degrees of the first valve and the second valve, the temperature adjustment upon each of the first region, the second region and the third region of the cooling table can be performed in a more precise way.

A path of the coolant between the chiller unit and the path group may be changed based on a switchover of an opening/closing state of the second valve group. Further, the second valve group may include a third valve, a fourth valve, a fifth valve and a sixth valve. The chiller unit and the third path may be connected with the third valve therebetween. The chiller unit and the first path may be connected with the fourth vale therebetween. A path between the third valve and the third path and a path between the fourth valve and the chiller unit may be connected with the fifth valve therebetween. A path between the chiller unit and the third valve and a path between the fourth valve and the first path may be connected with the sixth valve therebetween. Since the second valve group includes the third valve to the sixth valve, the switchover of the paths of the coolant between the chiller unit and the path group is enabled more securely.

The processing apparatus may further include a pressure control device and a heat transfer space. The heat transfer space may be provided between the electrostatic chuck and the cooling table, and extended along the electrostatic chuck. The pressure control device may be connected to the heat transfer space, and configured to adjust an internal pressure of the heat transfer space. A heat amount that can be conducted to the cooling table from the electrostatic chuck can be adjusted by adjusting the internal pressure of the heat transfer space. As a result, a rate (time and amount) of the heat generation can be precisely adjusted.

The heat transfer space may be airtightly partitioned into multiple regions, and the pressure control device may be connected to each of the multiple regions and configured to adjust an internal pressure of each of the multiple regions. Thus, since the internal pressure of the heat transfer space can be adjusted for each region of the heat transfer space individually, the rate (time and amount) of the heat generation can be precisely adjusted for each region of the heat transfer space individually.

In accordance with the exemplary embodiment as stated above, it is possible to provide a technique capable of performing temperature adjustment in response to a change in a distribution of a heat input amount

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a diagram schematically illustrating a processing apparatus according to an exemplary embodiment;

FIG. 2 is a diagram schematically illustrating a configuration of a pipeline system of the processing apparatus according to the exemplary embodiment;

FIG. 3 is a diagram for describing a supply sequence of a coolant into multiple paths within a cooling table from a chiller unit in the processing apparatus according to the exemplary embodiment;

FIG. 4 is a diagram for describing another supply sequence of the coolant into the multiple paths within the cooling table from the chiller unit in the processing apparatus according to the exemplary embodiment;

FIG. 5 is a diagram showing a relationship between a heat input amount and a temperature after a temperature adjustment in the processing apparatus according to the exemplary embodiment;

FIG. 6 is a diagram showing a relationship between a heat input amount and a temperature after a temperature adjustment in the processing apparatus according to the exemplary embodiment; and

FIG. 7 is a diagram showing another example of the processing apparatus according to the exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, various exemplary embodiments will be described in detail with reference to the accompanying drawings. In the various drawings, same or corresponding parts will be assigned same reference numerals.

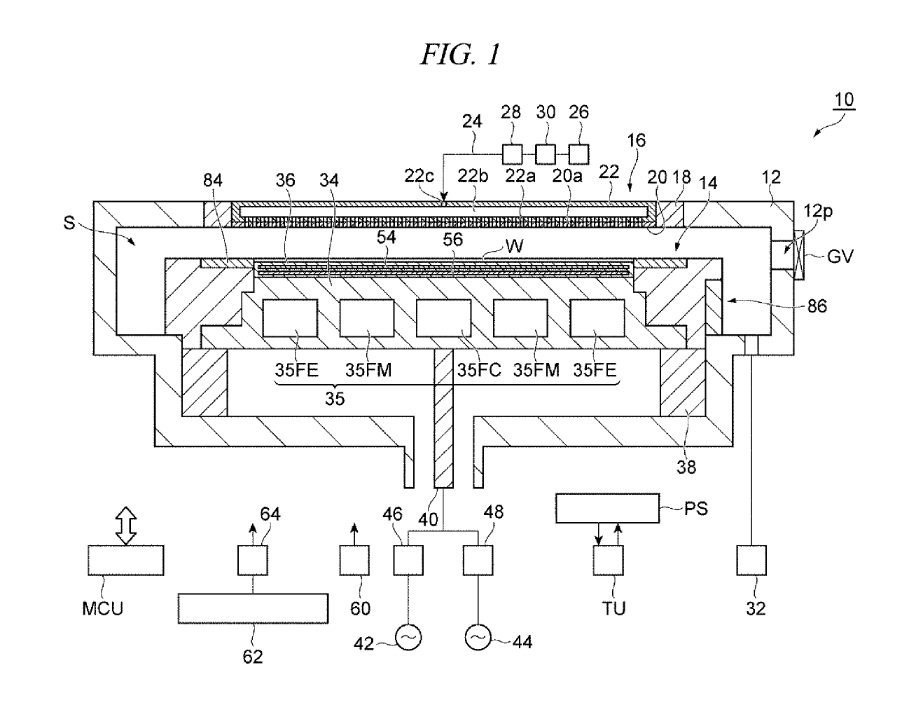

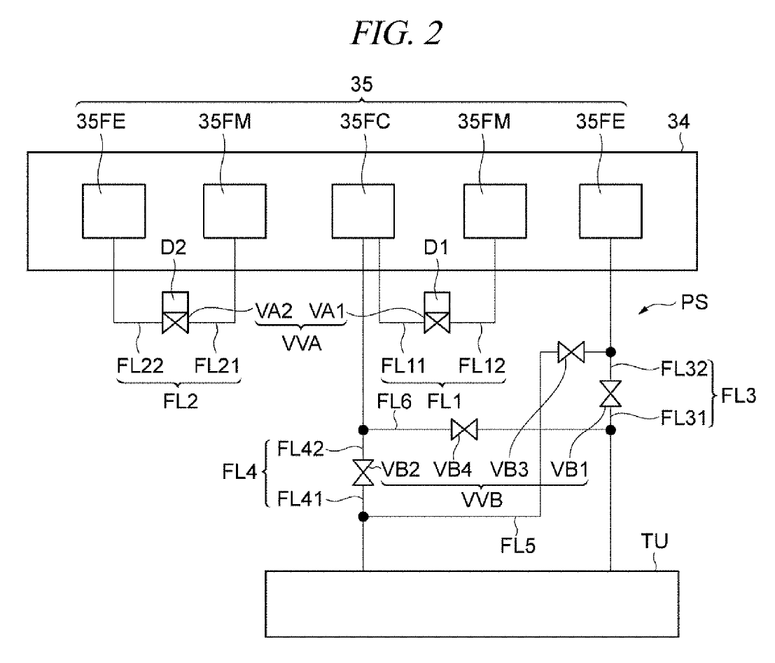

Referring to FIG. 1 and FIG. 2, a configuration of a processing apparatus according to an exemplary embodiment will be explained. FIG. 1 is a diagram schematically illustrating the processing apparatus according to the exemplary embodiment. FIG. 2 is a diagram schematically illustrating a configuration of a pipeline system of the processing apparatus according to the exemplary embodiment. A processing apparatus 10 shown in FIG. 1 and FIG. 2 is configured as a capacitively coupled plasma processing apparatus. The processing apparatus 10 is configured to process a processing target object (sometimes referred to as “processing target object W”). The processing apparatus 10 includes a chamber main body 12, a mounting table 14, an upper electrode 16, a pipeline 24, a gas source 26, a flow rate controller 28, a valve 30, a gas exhaust device 32, a high frequency power supply 42, a high frequency power supply 44, a matching device 46, a matching device 48, a DC power supply 60, a heater power supply 62, a filter 64, a controller MCU, a pipeline system PS, and a chiller unit TU. The chamber main body 12 includes an opening 12p, a supporting member 18, a ceiling plate 20, gas discharge holes 20a, a supporting body 22, communication holes 22a, a gas diffusion space 22b, a port 22c, and a gate valve GV. The mounting table 14 includes a cooling table 34, an electrostatic chuck 36, a supporting member 38, a power feed body 40, an attraction electrode 54, a heater 56, a focus ring 84, and an insulating member 86. The cooling table 34 is equipped with a path group 35, and this path group 35 includes a path 35FC (first path), a path 35FM (second path) and a path 35FE (third path).

The pipeline system PS is equipped with a detector D1, a detector D2, a valve group VVA (first valve group), and a valve group VVB (second valve group). The valve group VVA includes a valve VA1 (first valve) and a valve VA2 (second valve). The valve group VVB includes a valve VB1 (third valve), a valve VB2 (fourth valve), a valve VB3 (fifth valve) and a valve VB4 (sixth valve).

The pipeline system PS is also provided with a path FL1, a path FL2, a path FL3, a path FL4, a path FL5, a path FL6. The path FL1 includes a path FL11 and a path FL12. The path FL2 includes a path FL21 and a path FL22. The path FL3 includes a path FL31 and a path FL32. The path FL4 includes a path FL41 and a path FL42.

The chamber main body 12 has an approximately cylindrical shape, and an internal space thereof is configured as a processing space S in which the processing target object W is processed. The chamber main body 12 is made of, by way of example, but not limitation, aluminum. An alumite film and/or a film made of ceramic such as yttrium oxide having plasma resistance is formed on a surface of the chamber main body 12 at a side of the internal space thereof. The chamber main body 12 is electrically grounded. The opening 12p through which the processing target object W is carried into or out of the processing space S is formed at a sidewall of the chamber main body 12. The opening 12p is configured to be opened/closed by the gate valve GV. The processing target object W has a disk shape like a wafer.

The mounting table 14 is structured to mount thereon the processing target object W, and is provided within the chamber main body 12. The mounting table 14 is configured to support the processing target object W within the processing space S. The mounting table 14 has a function of attracting the processing target object W and a function of adjusting a temperature of the processing target object W, and has a structure in which a high frequency power is supplied to the cooling table 34 which mounts the electrostatic chuck 36 thereon. Details of the mounting table 14 will be described later.

The upper electrode 16 is disposed within an upper opening of the chamber main body 12, and is placed approximately in parallel with a lower electrode of the mounting table 14 to be described later. The insulating supporting member 18 is provided between the upper electrode 16 and the chamber main body 12.

The ceiling plate 20 has an approximately disk shape. The ceiling plate 20 may have conductivity. The ceiling plate 20 is made of, by way of non-limiting example, silicon or aluminum, and a ceramic film having plasma resistance is formed on a surface of the ceiling plate 20. The ceiling plate 20 is provided with the multiple gas discharge holes 20a. The gas discharge holes 20a are extended in an approximately vertical direction (in a direction heading toward the mounting table 14 from the ceiling plate 20).

The supporting body 22 is configured to support the ceiling plate 20 in a detachable manner. The supporting body 22 is made of, by way of non-limiting example, aluminum. The gas diffusion space 22b is formed in the supporting body 22. The multiple communication holes 22a are extended from the gas diffusion space 22b to communicate with the gas discharge holes 20a, respectively. The gas diffusion space 22b is connected to the pipeline 24 via the port 22c. The pipeline 24 is connected to the gas source 26. The flow rate controller 28 such as a mass flow controller and the valve 30 are provided at portions of the pipeline 24. The gas source 26, the flow rate controller 28 and the valve 30 constitute a gas supply unit in the exemplary embodiment.

The gas exhaust device 32 includes one or more pumps such as a turbo molecular pump or a dry pump; and a pressure control valve. The gas exhaust device 32 is connected to a gas exhaust opening formed at the chamber main body 12.

When the processing apparatus 10 is operated, the processing target object W is placed on and held by the mounting table 14. A processing gas from the gas source 26 is supplied into the chamber main body 12, and as the gas exhaust device 32 is operated, the processing space S within the chamber main body 12 is decompressed. A high frequency electric field is formed between the upper electrode 16 and the lower electrode of the mounting table 14. Accordingly, the processing gas is dissociated, so that the processing target object W is processed by active species of molecules and/or atoms in the processing gas. In this processing, the individual components of the processing apparatus 10 are controlled by the controller MCU.

The mounting table 14 is equipped with the cooling table 34 and the electrostatic chuck 36. The electrostatic chuck 36 is provided on the cooling table 34. The cooling table 34 is supported by the supporting member 38 which is extended upwards from a bottom portion of the chamber main body 12. The supporting member 38 is an insulating member, and is made of, by way of non-limiting example, aluminum oxide (alumina). The supporting member 38 has an approximately cylindrical shape.

The power feed body 40 is connected to the cooling table 34. The power feed body 40 is implemented by, for example, a power feed rod, and is connected to a bottom surface of the cooling table 34. The power feed body 40 is made of aluminum or an aluminum alloy. The power feed body 40 is electrically connected to the high frequency power supply 42 and the high frequency power supply 44 which are provided at an outside of the chamber main body 12. The high frequency power supply 42 is configured to generate a first high frequency power for plasma generation. The first high frequency power has a frequency of, e.g., 40 MHz. The high frequency power supply 44 is configured to generate a second high frequency power for ion attraction. The second high frequency power has a frequency of, e.g., 13.56 MHz.

The high frequency power supply 42 is connected to the power feed body 40 via the matching device 46. The matching device 46 is equipped with a matching circuit configured to match an impedance at a load side of the high frequency power supply 42 with an output impedance of the high frequency power supply 42. The high frequency power supply 44 is connected to the power feed body 40 via the matching device 48. The matching device 48 is equipped with a matching circuit configured to match an impedance at a load side of the high frequency power supply 44 with an output impedance of the high frequency power supply 44.

The cooling tale 34 is made of a metal having conductivity, such as aluminum. The cooling table 34 has an approximately disk shape. The cooling table 34 has a region RC (first region), a region RM (second region) and a region RE (third region). The region RC, the region RM and the region RE are arranged along a surface of the electrostatic chuck 36 which is provided on the cooling table 34. In a plan view seen from above the corresponding surface of the electrostatic chuck 36, the region RC is disposed at a center of the cooling table 34. In the plan view seen from above the corresponding surface of the electrostatic chuck 36, the region RM is disposed to surround the region RC. Further, in the plan view seen from above the corresponding surface of the electrostatic chuck 36, the region RE is disposed to surround the region RC and the region RM. The region RM is disposed between the region RC and the region RE. A region of the electrostatic chuck 36 including a center of the corresponding surface thereof is disposed on the region RC of the cooling table 34; a region of the corresponding surface of the electrostatic chuck 36 between the region including the center of the electrostatic chuck 36 and a region including an edge of the electrostatic chuck 36 is disposed on the region RM; and a region of the corresponding surface of the electrostatic chuck 36 including the edge of the electrostatic chuck 36 is disposed on the region RE.

The cooling table 34 is connected to the pipeline system PS, and a coolant supplied through the pipeline system PS (that is, a coolant supplied from the chiller unit TU) is flown therein. The cooling table 34 is provided with the path group 35 for the coolant. The path group 35 is connected to the pipeline system PS, and the coolant from the chiller unit TU is flown through the path group 35. The path 35FC, the path 35FM and the path 35FE are arranged along the surface of the electrostatic chuck 36. The path 35FC is provided in the region RC. The path 35FM is provided in the region RM. The path 35FE is provided in the region RE. In the plan view seen from above the surface of the electrostatic chuck 36, the path 35FC is provided at the center of the cooling table 34. In the plan view seen from above the surface of the electrostatic chuck 36, the path 35FM is disposed to surround the path 35FC. Further, in the plan view seen from above the surface of the electrostatic chuck 36, the path 35FE is disposed to surround the path 35FM and the path 35FC. The region of the electrostatic chuck 36 including the center of the surface thereof is disposed on the path 35FC; the region of the corresponding surface of the electrostatic chuck 36 between the region including the center of the electrostatic chuck 36 and the region including the edge of the electrostatic chuck 36 is disposed on the path 35FM; and the region of the surface of the electrostatic chuck 36 including the edge of the electrostatic chuck 36 is disposed on the path 35FE.

The coolant is supplied into the path group 35 from the chiller unit TU. The chiller unit TU is configured to output the coolant. In the exemplary embodiment, the coolant supplied to the path group 35 may be of a type in which heat is absorbed by vaporization thereof to perform cooling. This coolant may be, for example, a hydrofluorocarbon-based coolant.

The electrostatic chuck 36 is provided on the cooling table 34. The cooling table 34 is configured as the lower electrode. The cooling table 34 has conductivity. The cooling table 34 may be made of, by way of example, ceramic prepared by aluminum nitride or silicon carbide having conductivity, or may be made of a metal (e.g., titanium).

The electrostatic chuck 36 is provided on the cooling table 34. The electrostatic chuck 36 is coupled to the cooling table 34 by metal bonding with a metal provided between the electrostatic chuck 36 and the cooling table 34. The electrostatic chuck 36 has an approximately disk shape, and is made of ceramic such as, but not limited to, aluminum oxide (alumina).

The electrostatic chuck 36 is equipped with the attraction electrode 54 embedded therein. The attraction electrode 54 is implemented by an electrode film, and is electrically connected to the DC power supply 60. If a DC voltage is applied to the attraction electrode 54 from the DC power supply 60, the electrostatic chuck 36 generates an electrostatic force such as a Coulomb force and holds the processing target object W by this electrostatic force. The electrostatic chuck 36 is further equipped with the heater 56 embedded therein. The heater 56 is provided in the electrostatic chuck 36, and connected to the heater power supply 62. In the exemplary embodiment, the filter 64 is provided between the heater 56 and the heater power supply 62 to suppress the high frequency power from being introduced into the heater power supply 62.

The focus ring 84 is disposed to surround the electrostatic chuck 36. The focus ring 84 is extended along the surface of the electrostatic chuck 36 (the surface of the processing target object W).

The cooling table 34 and the like of the mounting table 14 is covered by one or more insulating members 86 on an outer surface thereof. The one or more insulating members 86 are made of, by way of example, but not limitation, aluminum oxide or quartz.

The controller MCU is configured to control the individual components of the processing apparatus 10. By way of example, the controller MCU may be a computer device including a processer and a storage device such as a memory. The controller MCU may control the individual components of the processing apparatus 10 by being operated according to programs and recipes stored in the storage device.

Now, the pipeline system PS applicable to the processing apparatus 10 will be elaborated. FIG. 2 is a diagram illustrating a configuration of the pipeline system according to the exemplary embodiment. The pipeline system PS shown in FIG. 2 includes the multiple valves (the valve VA1 and the valve VA2 of the valve group VVA, and the valve VB1, the valve VB2, the valve VB3 and the VB4 of the valve group VVB). The pipeline system PS is connected to the chiller unit TU and allows the coolant outputted from the chiller unit TU to flow therethrough. In the pipeline system PS, the chiller unit TU is connected to each of the path 35FC, the path 35FM and the path 35FE, and the coolant is supplied from the chiller unit TU into each of the path 35FC, the path 35FM and the path 35FE. By changing opening/closing states of the valves of the valve group VVB, a path of the coolant between the chiller unit TU and the path group 35 can be changed. The pipeline system PS is configured such that, as opening/closing operations of the multiple valves are controlled by the controller MCU, a supply sequence of the coolant into the path 35FC, the path 35FM and the path 35FE can be changed. To elaborate, in the pipeline system PS, as the sequence of supplying the coolant from the chiller unit TU into the path 35FC, the path 35FM and the path 35FE, two supply modes (a first supply mode and a second supply mode) to be described later can be implemented under the control of the controller MCU.

In the path group 35, the path 35FC and the path 35FM are connected and the path 35FM and the path 35FE are connected via the valve group VVA. The path 35FC and the path 35FM is connected with the valve VA1 therebetween, and the path 35FM and the path 35FE are connected with the valve VA2 therebetween. The path 35FC and the path 35FM are connected with the path FL1 therebetween. The path FL1 is provided with the valve VA1. The path 35FC and the valve VA1 are connected with the path FL11 therebetween. The valve VA1 and the path 35FM are connected with the path FL12 therebetween. The path 35FM and the path 35FE are connected with the path FL2 therebetween. The path FL2 is provided with the valve VA2. The path 35FM and the valve VA2 are connected with the path FL21 therebetween. The valve VA2 and the path 35FE are connected with the path FL22 therebetween.

An opening degree of the valve VA1 and an opening degree of the valve VA2 may be variable. The valve VA1 and the valve VA2 may be of a type in which, for example, a straight type metal diaphragm is provided and the opening degree is adjustable with an air pressure. By using this type of valve for the valve VA1 and the valve VA2, a pressure loss can be reduced.

The valve VA1 is equipped with the detector D1. The detector D1 may be disposed at one of two ends of the valve VA1 (that is, at either of an end connected to the path FL11 and an end connected to the path FL12). The detector D1 is configured to detect a pressure or a temperature of the coolant passing through the valve VA1 and send a detection result to the controller MCU. The valve VA2 is equipped with the detector D2. The detector D2 may be disposed at one of two ends of the valve VA2 (that is, at either of an end connected to the path FL21 and an end connected to the path FL22). The detector D2 is configured to detect a pressure or a temperature of the coolant passing through the valve VA2 and send a detection result to the controller MCU.

In the pipeline system PS, the chiller unit TU and the path 35FE are connected with the valve VB1 therebetween. In the pipeline system PS, the chiller unit TU and the path 35FC are connected with the valve VB2 therebetween. In the pipeline system PS, a path between the valve VB1 and the path 35FE and a path between the valve VB2 and the chiller unit TU are connected with the valve VB3 therebetween. Further, in the pipeline system PS, a path between the chiller unit TU and the valve VB1 and a path between the valve VB2 and the path 35FC are connected with the valve VB4 therebetween.

To be more specific, the chiller unit TU and the path group 35 are connected via the valve group VVB. The chiller unit TU and the path 35FE are connected with the path FL3 therebetween. The path FL3 is provided with the valve VB1. The chiller unit TU and the valve VB1 are connected with the path FL31 therebetween. The valve VB1 and the path 35FE are connected with the path FL32 therebetween. The chiller unit TU and the path 35FC are connected with the path FL4 therebetween. The path FL4 is provided with the valve VB2. The chiller unit TU and the valve VB2 are connected with the path FL41 therebetween. The valve VB2 and the path 35FC are connected with the path FL42 therebetween. The path FL32 and the path FL41 are connected with the path FL5. The path FL5 is provided with the valve VB3. The path FL31 and the path FL42 are connected with the path FL6 therebetween. The path FL6 is provided with the valve VB4.

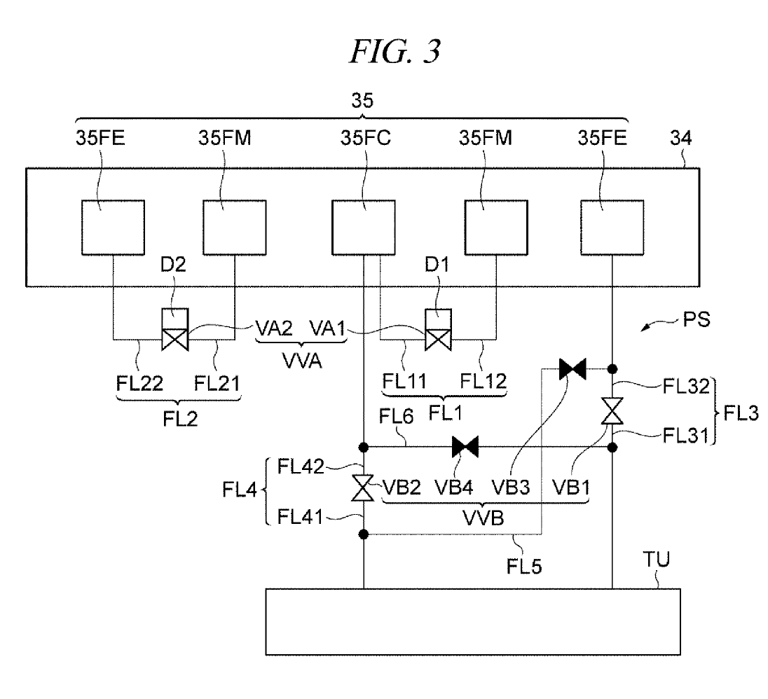

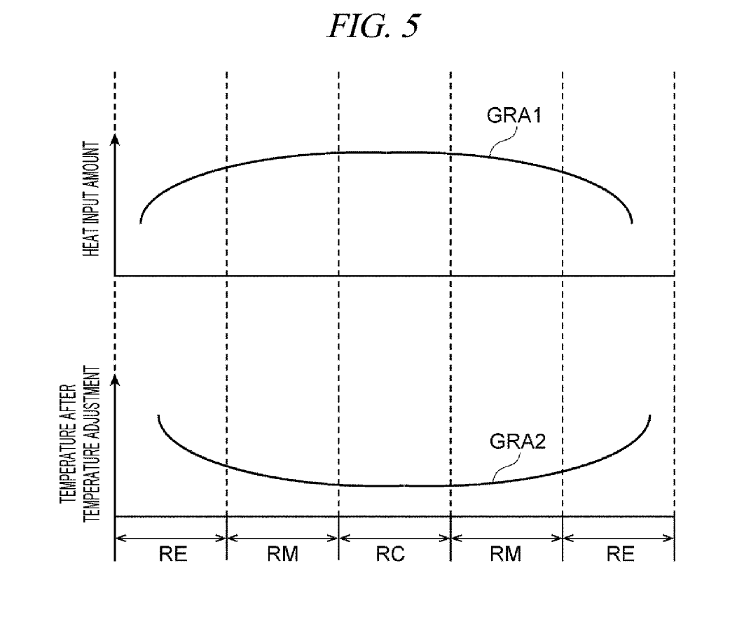

Referring to FIG. 3 and FIG. 5, the first supply mode will be explained. FIG. 3 is a diagram for describing a supply sequence of the coolant from the chiller unit into the multiple paths within the cooling table in the processing apparatus according to the exemplary embodiment. FIG. 5 is a diagram showing a relationship between a heat input amount and a temperature after a temperature adjustment in the processing apparatus according to the exemplary embodiment. A horizontal axis of FIG. 5 indicates a position (the region RC, the region RM and the region RE) within the cooling table 34, and two vertical axes of FIG. 5 respectively indicate the heat input amount and the temperature after the temperature adjustment. In the first supply mode, the valve VB3 and the valve VB4 are closed (the valve VB3 and the valve VB4 are colored black in FIG. 3), and the valve VA1, the valve VA2, the valve VB1 and the valve VB2 are opened. The opening degrees (ranging from 0% (completely closed state) to 100% (completely opened state)) of the valve VA1 and the valve VA2 can be adjusted by the controller MCU (or manually). By adjusting the opening degrees of the valve VA1 and the valve VA2, the pressure of the coolant in the path 35FM and the pressure of the coolant in the path 35FC can be individually adjusted in a detailed manner, so that a distribution of the temperature after the temperature adjustment by the coolant can be adjusted in a detailed manner as well.

In the first supply mode, the coolant outputted from the chiller unit TU reaches the path 35FE via the valve VB1, reaches the path 35FM from the path 35FE via the valve VA2, reaches the path 35FC from the path 35FM via the valve VA1, and then, reaches the chiller unit TU from the path 35FC via the valve VB2. That is, the coolant outputted from the chiller unit TU flows in the order of the path 35FE, the path 35FM and the path 35FC. As for the pressure (vaporization (temperature adjustment) temperature) of the coolant within the path of the coolant in the pipeline system PS, the pressure of the coolant at an upstream side is higher than the pressure of the coolant at a downstream side, and as the pressure of the coolant increases, the temperature adjustment to a high temperature is achieved. In the first supply mode, since the pressure of the coolant is highest in the order of the path 35FE, the path 35FM and the path 35FC, the temperature after the temperature adjustment is highest in the order of the path 35FE (region RE), the path 35FM (region RM) and the path 35FC (region RC). Accordingly, in case that the heat input amount of plasma to the cooling table 34 is distributed such that, as shown on a graph GRA1 of FIG. 5, the heat input amount is largest in the order of the region RC, the region RM and the region RE, the temperature after the temperature adjustment upon the cooling table 34 by the coolant may become to have the reverse distribution to the distribution of the heat input amount of the plasma as the first supply mode is performed, as shown on a graph GRA2 of FIG. 5. Therefore, a temperature of a region of the processing target object W on the region RC, a temperature of a region of the processing target object W on the region RM and a temperature of a region of the processing target object W on the region RE can be made same regardless of the distribution of the heat input amount of the plasma.

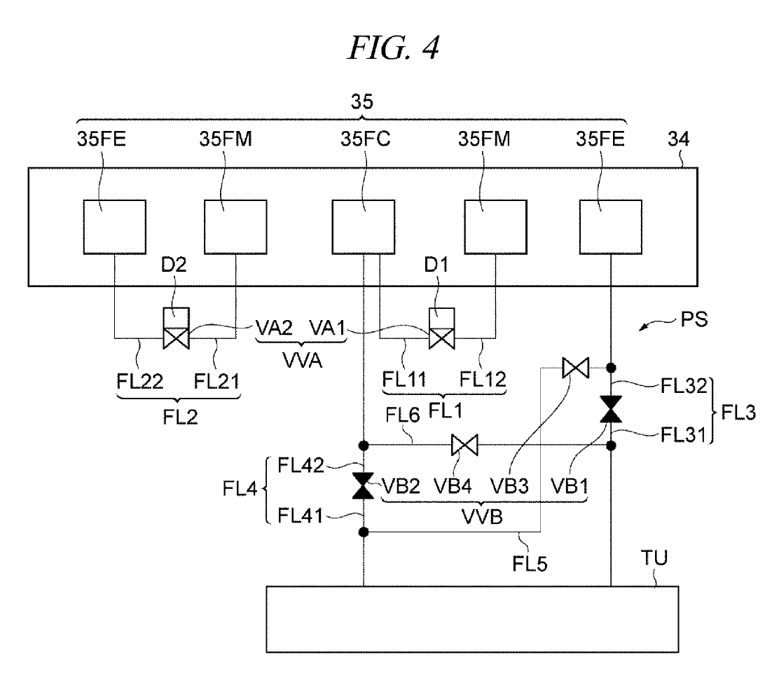

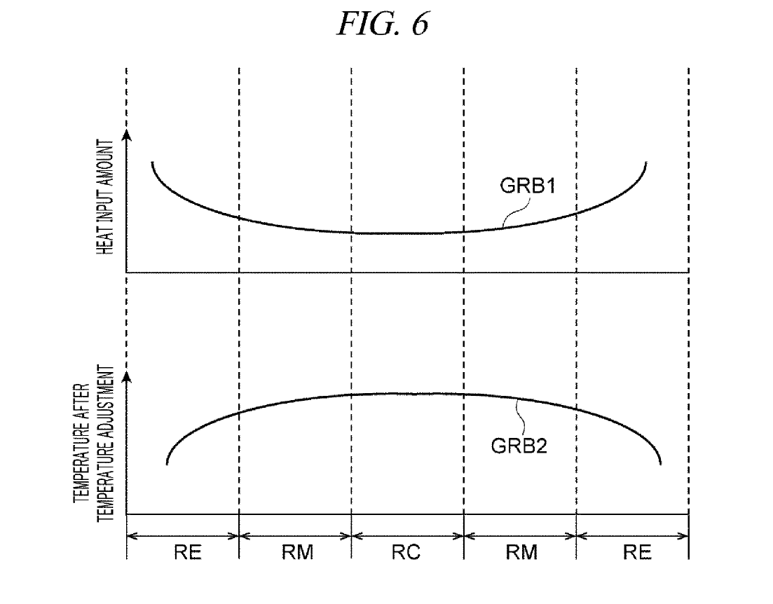

Now, referring to FIG. 4 and FIG. 6, the second supply mode will be explained. FIG. 4 is a diagram for describing another supply sequence of the coolant from the chiller unit into the multiple paths within the cooling table in the processing apparatus according to the exemplary embodiment. FIG. 6 is a diagram showing a relationship between a heat input amount and a temperature after a temperature adjustment in the processing apparatus according to the exemplary embodiment. A horizontal axis of FIG. 6 indicates a position (the region RC, the region RM and the region RE) within the cooling table 34, and two vertical axes of FIG. 6 respectively indicate the heat input amount and the temperature after the temperature adjustment. In the second supply mode, the valve VB1 and the valve VB2 are closed (the valve VB1 and the valve VB2 are colored black in FIG. 4), and the valve VA1, the valve VA2, the valve VB3 and the valve VB4 are opened. The opening degrees (ranging from 0% (completely closed state) to 100% (completely opened state)) of the valve VA1 and the valve VA2 can be adjusted by the controller MCU (or manually). By adjusting the opening degrees of the valve VA1 and the valve VA2, the pressure of the coolant in the path 35FM and the pressure of the coolant in the path 35FE can be individually adjusted in a detailed manner, so that a distribution of the temperature after the temperature adjustment by the coolant can be adjusted in a detailed manner as well.

In the second supply mode, the coolant outputted from the chiller unit TU reaches the path 35FC via the valve VB4, reaches the path 35FM from the path 35FC via the valve VA1, reaches the path 35FE from the path 35FM via the valve VA2, and then, reaches the chiller unit TU from the path 35FE via the valve VB3. That is, the coolant outputted from the chiller unit TU flows in the order of the path 35FC, the path 35FM and the path 35FE. As for the pressure (vaporization (temperature adjustment) temperature) of the coolant within the path of the coolant of the pipeline system PS, the pressure of the coolant at the upstream side is higher than the pressure of the coolant at the downstream side, and as the pressure of the coolant increases, the temperature adjustment to a high temperature is achieved. In the second supply mode, since the pressure of the coolant is highest in the order of the path 35FC, the path 35FM and the path 35FE, the temperature after the temperature adjustment is highest in the order of the path 35FC (region RC), the path 35FM (region RM) and the path 35FE (region RE). Accordingly, in case that the heat input amount of plasma to the cooling table 34 is distributed such that, as shown on a graph GRB1 of FIG. 6, the heat input amount is largest in the order of the region RE, the region RM and the region RC, the temperature after the temperature adjustment upon the cooling table 34 by the coolant may become to have the reverse distribution to the distribution of the heat input amount of the plasma as the second supply mode is performed, as shown on a graph GRB2 of FIG. 6. Therefore, the temperature of the region of the processing target object W on the region RE, the temperature of the region of the processing target object W on the region RM and the temperature of the region of the processing target object W on the region RC can be made same regardless of the distribution of the heat input amount of the plasma.

As stated above, by using the above-described first supply mode and the second supply mode and, also, by adjusting the opening degrees of the valve VA1 and the valve VA2 individually in the detailed manner, the temperature of the processing target object W can be made approximately uniform regardless of the distribution of the heat input amount on the processing target object W and the variation of this distribution.

In the processing apparatus 10 according to the exemplary embodiment, the path 35FC, the path 35FM and the path 35FE of the path group for allowing the coolant to flow in the region RC, the region RM and the region RE of the cooling table 34 respectively are provided in the cooling table 34 of the mounting table 14 configured to mount the processing target object W thereon; the path 35FC and the path 35FM are connected and the path 35FM and the path 35FE are connected by the valve group VVA; and the chiller unit TU and the path group 35 provided in the cooling table 34 are connected with the valve group VVB therebetween. Accordingly, by adjusting the opening/closing state of the valve group VVA and the opening/closing state of the valve group VVB, the path and the pressure of the coolant flowing in the cooling table 34 can be adjusted for each of the region RC, the region RM and the region RE of the cooling table 34 individually, so that the temperature adjustment upon the cooling table 34 can be performed in a detailed manner. Therefore, the temperature of the processing target object W placed on the cooling table 34 can be easily made approximately uniform regardless of the distribution of the heat input amount of the plasma.

Further, the connection between the path 35FC and the path 35FM and the connection between the path 35FM and the path 35FE are respectively accomplished with the separately provided valve VA1 and the valve VA2 therebetween. Thus, by adjusting these valves individually, the temperature adjustment upon each of the region RC, the region RM and the region RE of the cooling table 34 can be performed individually, so that more detailed temperature control can be achieved.

Furthermore, the valve VA1 provided between the path 35FC and the path 35FM and the valve VA2 provided between the path 35FM and the path 35FE are configured to vary the opening degrees thereof. Thus, by adjusting the opening degrees of the valve VA1 and the valve VA2, the temperature adjustment upon each of the region RC, the region RM and the region RE of the cooling table 34 can be performed in a more precise way.

In addition, since the valve group VVB includes the valves VB1 to VB4, the switchover of the paths of the coolant between the chiller unit TU and the path group 35 is enabled more securely.

The above description of the exemplary embodiment is provided for the purpose of illustration, and it would be understood by those skilled in the art that various changes and modifications may be made without changing technical conception and essential features of the exemplary embodiment. The scope of the inventive concept is defined by the following claims and their equivalents rather than by the detailed description of the exemplary embodiment. It shall be understood that all modifications and embodiments conceived from the meaning and scope of the claims and their equivalents are included in the scope of the inventive concept.

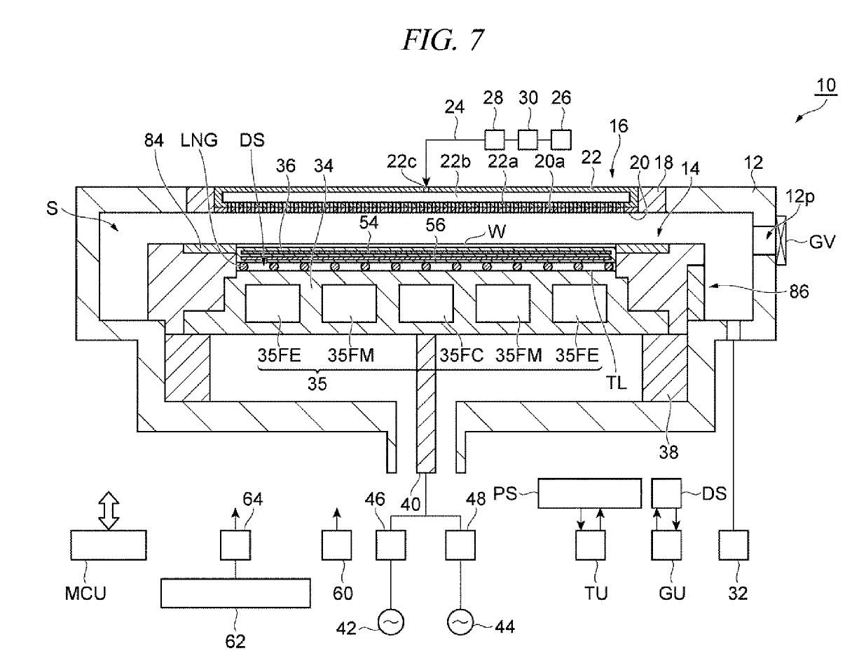

By way of example, as shown in FIG. 7, the processing apparatus 10 according to the exemplary embodiment may have a configuration in which a heat transfer space TL is provided between the cooling table 34 and the electrostatic chuck 36. FIG. 7 is a diagram schematically illustrating another example of the processing apparatus 10 according to the exemplary embodiment. The processing apparatus 10 shown in FIG. 7 further includes the heat transfer space TL, a pressure control device GU and multiple elastic members LNG. The heat transfer space TL is provided between the electrostatic chuck 36 and the cooling table 34 and extended along the electrostatic chuck 36.

Further, the processing apparatus 10 shown in FIG. 7 further includes the multiple elastic members LNG, and the heat transfer space TL of the processing apparatus 10 shown in FIG. 7 is airtightly partitioned into multiple regions DS by the multiple elastic members LNG. Within the heat transfer space TL, the respective regions DS are partitioned by the elastic members LNG. The elastic members LNG are O-rings. The number and the shape of the regions DS within the heat transfer space TL may be modified in various ways depending on conditions involved and so forth. The pressure control device GU is connected to each of the multiple regions DS, and adjusts an internal pressure of each of the multiple regions DS individually by a supply/suction of a gas into/from each region DS.

Heat insulating property within the heat transfer space TL (particularly, within each of the multiple regions DS) increases as the internal pressure thereof decreases. Accordingly, in case of performing rapid heat generation upon the processing target object W on the cooling table 34, the heat insulating property is lowered by setting the internal pressure of the heat transfer space TL (particularly, each of the multiple regions DS) to be relatively high. In case of increasing the temperature of the processing target object W on the cooling table 34 by the heat input from the plasma, the heat insulating property is increased by setting the internal pressure of the heat transfer space TL (particularly, each of the multiple regions DS) to be relatively low.

As stated above, in the processing apparatus 10 illustrated in FIG. 7, a heat amount that can be conducted to the cooling table 34 from the electrostatic chuck 36 can be adjusted by adjusting the internal pressure of the heat transfer space TL. As a result, a rate (time and amount) of the heat generation can be precisely adjusted. Further, since the internal pressure of the heat transfer space TL can be adjusted for each region DS of the heat transfer space TL individually, the rate (time and amount) of the heat generation can be precisely adjusted for each region DS of the heat transfer space TL individually.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A processing apparatus for a processing target object, comprising:
a chamber main body;
a mounting table which is provided within the chamber main body and configured to mount the processing target object thereon;
a chiller unit configured to output a coolant; and
a pipeline system which is connected to the chiller unit and configured to allow the coolant to flow therein,
wherein the mounting table comprises:
a cooling table which is connected to the pipeline system and in which the coolant supplied through the pipeline system is flown; and
an electrostatic chuck provided on the cooling table,
the cooling table comprises a first region, a second region, a third region, and a path group which is connected to the pipeline system and configured to allow the coolant to flow therethrough,
the first region, the second region and the third region are arranged along a surface of the electrostatic chuck,
the first region is provided at a center portion of the cooling table when viewed from above the electrostatic chuck,
the second region is provided to surround the first region when viewed from above the electrostatic chuck,
the third region is provided to surround the first region and the second region when viewed from above the electrostatic chuck,
the path group comprises a first path, a second path and a third path,
the first path is provided in the first region,
the second path is provided in the second region,
the third path is provided in the third region,
the pipeline system comprises a first valve group and a second valve group,
in the path group, the first path and the second path are connected with the first valve group therebetween, and the second path and the third path are connected with the first valve group therebetween, and
the chiller unit and the path group are connected with the second valve group therebetween.

2. The processing apparatus of claim 1,
wherein the first valve group comprises a first valve and a second valve,
the first path and the second path are connected with the first valve therebetween, and
the second path and the third path are connected with the second valve therebetween.

3. The processing apparatus of claim 2,
wherein an opening degree of the first valve and an opening degree of the second valve are allowed to be varied.

4. The processing apparatus of claim 1,
wherein a path of the coolant between the chiller unit and the path group is changed based on a switchover of an opening/closing state of the second valve group.

5. The processing apparatus of claim 1,
wherein the second valve group comprises a third valve, a fourth valve, a fifth valve and a sixth valve,
the chiller unit and the third path are connected with the third valve therebetween,
the chiller unit and the first path are connected with the fourth vale therebetween,
a path between the third valve and the third path and a path between the fourth valve and the chiller unit are connected with the fifth valve therebetween, and
a path between the chiller unit and the third valve and a path between the fourth valve and the first path are connected with the sixth valve therebetween.

6. The processing apparatus of claim 1, further comprising:
a pressure control device and a heat transfer space,
wherein the heat transfer space is provided between the electrostatic chuck and the cooling table, and extended along the electrostatic chuck, and
the pressure control device is connected to the heat transfer space, and configured to adjust an internal pressure of the heat transfer space.

7. The processing apparatus of claim 6,
wherein the heat transfer space is airtightly partitioned into multiple regions, and
the pressure control device is connected to each of the multiple regions and configured to adjust an internal pressure of each of the multiple regions.
